(19) United States
(12) Patent Application Publication
(10) Pub. No.: US 2016/0327596 A1
(43) Pub. Date: Nov. 10, 2016

(54) Behavioral Analysis To Detect Anomalous Electromagnetic Emissions

(71) Applicant: QUALCOMM Incorporated, San Diego, CA (US)

(72) Inventors: Mastooreh Salajegheh, San Jose, CA (US); Govindarajan Krishnamurthi, Palo Alto, CA (US); Mihai Christodorescu, San Jose, CA (US); Rajarshi Gupta, Sunnyvale, CA (US); Vinay Sridhara, Santa Clara, CA (US); Patrick Hughes, Dana Point, CA (US)

(21) Appl. No.: 14/705,546

(22) Filed: May 6, 2015

(51) Int. Cl. G01R 29/08; G01R 31/00

(52) U.S. Cl. CPC G01R 29/0814; G01R 31/001

(57) ABSTRACT

Systems, methods, and devices of the various aspects enable detecting anomalous electromagnetic (EM) emissions from among a plurality of electronic devices. A device processor may receive EM emissions of a plurality of electronic devices, wherein the receiving device has no previous information about any of the plurality of electronic devices. The device processor may cross-correlate the EM emissions of the plurality of electronic devices over time. The device processor may identify a difference of the cross-correlated EM emissions from earlier cross-correlated EM emissions. The device processor may determine that the difference of the cross-correlated EM emissions from the earlier cross-correlated EM emissions indicates an anomaly in one or more of the plurality of electronic devices.

### BACKGROUND

The proliferation of electrical appliances, electronics, and communication devices has radically altered the environment in which people live, work, and play. Electronic and electrical devices are relied on to perform a wide variety of tasks in nearly every aspect of daily life. Consequently, these commonly used convenience devices are subject to wear and tear over time, in particular when such devices are used every day, in some cases continuously. The failure of one of these devices can have consequences ranging from the merely annoying to the downright dangerous. It is of importance to detect incipient failure or a change or decrease in performance or function of any of these devices, on which so many rely to perform so much.

### SUMMARY

Systems, methods, and devices of various aspects enable a receiving device to detect anomalous electromagnetic (EM) emissions from among a plurality of electronic devices when the receiving device has no previous information about any of the plurality of electronic devices by receiving EM emissions of a plurality of electronic devices, cross-correlating the EM emissions of the plurality of electronic devices over time, identifying a difference of the cross-correlated EM emissions from earlier cross-correlated EM emissions, and determining that the difference of the cross-correlated EM emissions from the earlier cross-correlated EM emissions indicates an anomaly in one or more of the plurality of electronic devices. In some aspects, cross-correlating the EM emissions of the plurality of electronic devices over time may include calculating a trend of the cross-correlated EM emissions over time using a statistical analysis of the EM emissions. In some aspects, identifying a difference of the cross-correlated EM emissions from earlier cross-correlated EM emissions may include identifying a difference of the cross-correlated EM emissions and the calculated trend.

In some aspects, determining that the difference of the cross-correlated EM emissions from the earlier cross-correlated EM emissions indicates an anomaly in one or more of the plurality of electronic devices may include determining that the difference of the cross-correlated EM emissions and the calculated trend indicates an anomaly in one or more of the plurality of electronic devices. In some aspects, calculating a trend of the cross-correlated EM emissions over time using a statistical analysis of the EM emissions may include determining a trend characteristic of the calculated trend. In some aspects, the trend characteristic may include one or more of a lock-step trend, a time-shifted trend, and a substantially uncorrelated trend. In some aspects, identifying a difference of the cross-correlated EM emissions from earlier cross-correlated EM emissions may include identifying a difference of the cross-correlated EM emissions and the determine trend characteristic.

In some aspects, determining that the difference of the cross-correlated EM emissions from the earlier cross-correlated EM emissions indicates an anomaly in one or more of the plurality of electronic devices may include determining that the difference of the cross-correlated EM emissions and the determine trend characteristic indicates an anomaly in one or more of the plurality of electronic devices. In some aspects, identifying a difference of the cross-correlated EM emissions from earlier cross-correlated EM emissions may include determining at least one anomaly threshold based on the cross-correlated EM emissions of the plurality of electronic devices over time, comparing the cross-correlated EM emissions of the plurality of electronic devices to the at least one anomaly threshold, and calculating the difference from the cross-correlated EM emissions relative to the determined at least one anomaly threshold. In some aspects, determining that the difference of the cross-correlated EM emissions from the earlier cross-correlated EM emissions indicates an anomaly in one or more of the plurality of electronic devices may include determining that the calculated difference from the cross-correlated EM emissions meets the at least one anomaly threshold.

Further aspects include a computing device including a processor configured with processor-executable instructions to perform operations of the aspect methods described above. Further aspects include a non-transitory processor-readable storage medium having stored thereon processor-executable software instructions configured to cause a processor to perform operations of the aspect methods described above. Further aspects include a computing device that includes means for performing functions of the operations of the aspect methods described above.

### BRIEF DESCRIPTION OF THE DRAWINGS

The accompanying drawings, which are incorporated herein and constitute part of this specification, illustrate exemplary aspects, and together with the general description given above and the detailed description given below, serve to explain the features of the various aspects.

FIG. 1 is an architectural diagram illustrating an example system-on-chip suitable for implementing the various aspects.

FIG. 2 is a block diagram illustrating example logical components and information flows in an RF environment characterization system suitable for use with the various aspects.

FIG. 3 is a process flow diagram illustrating an aspect method for detecting anomalous electromagnetic (EM) emissions from among a plurality of electronic devices in accordance with the various aspects.

FIG. 4 is a process flow diagram illustrating another aspect method for detecting anomalous EM emissions from among a plurality of electronic devices in accordance with the various aspects.

FIG. 5 is a process flow diagram illustrating another aspect method for detecting anomalous EM emissions from among a plurality of electronic devices in accordance with the various aspects.

FIG. 6 is a component block diagram of a mobile device suitable for use with various aspects.

### DETAILED DESCRIPTION

The various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the various aspects or the claims.

The various aspects include methods, and receiving devices configured to implement the methods, of detecting anomalous electromagnetic (EM) emissions from among a plurality of electronic devices. Electronic devices, such as electrical appliances, electronics, and communication devices, all emit electromagnetic signals as part of their electronic operations. In some cases the EM emissions may be characteristic of their operating state or behavior. For example, an electronic motor (e.g., the compressor in a refrigerator) will emit EM signals that include cycles reflective of rotations of the motor rotor and changes in magnetic fields in the windings, as well as signals consistent with the 50 Hz or 60 Hz alternating current (AC) driving the motor. Where electronic devices are in proximity to one another such that they experience a common temperature and lighting environment, and potentially a common power source, their behaviors may influence each other or their behaviors may be influenced by a common environmental factor (e.g., frequency or power level of a common power source). Consequently, the electromagnetic signals emitted by two or more electrical devices close to each other may exhibit some correlation patterns. For example, when an electric oven is on in the kitchen, the rise in temperature it causes may result in a near refrigerator cycling its compressor more frequently. Thus, the EM emissions from the heating elements of an electric oven may be correlated with more frequent EM emissions characteristic of the refrigerator's compressor motor. Similar correlations of EM emissions from the refrigerator compressor may be observed with an air conditioning system, a central heating system, and an electronic thermostat.

In the various aspects, a receiving device (i.e., a computing device configured to receive EM emissions) may receive EM emissions of a plurality of electrical and electronic devices (referred to herein as “electronic devices” for conciseness) and the receiving device may cross-correlate the EM emissions of the plurality of electronic devices over time. In the various aspects, the receiving device is not informed of “normal” or “abnormal” EM emissions of any devices that may be monitored. Instead, the receiving device uses the observed EM emissions, and particularly cross-correlations among the observed EM emissions from a plurality of devices, to detect when an anomaly condition exists. The receiving device may evaluate EM emissions that are received to determine whether there is a difference between the received EM emissions and cross-correlated EM emissions that have been observed over time. If such a difference is observed, the receiving device may determine whether the difference indicates an anomaly in one or more of the plurality of electronic devices. This determination may be accomplished by comparing the observed difference to a threshold, which may be determined over time based on observed variability in cross-correlated EM emissions. Such an anomaly may be indicative of a change in behavior of one or more of the electronic devices emitting EM radiation. When such an anomaly is recognized, the receiving device may take an action, such as alerting an operator, which may enable detection of an incipient or imminent fault or failure of one or more of the electronic devices.

A receiving device may be configured to receive EM emissions from a plurality of electronic devices. A receiving device may include a portable electronic device, such as a mobile communication device, or another similar device that may be configured to receive EM emissions from a plurality of electronic devices. The receiving device may have no prior information about the electronic devices from which it receives EM emissions. For example, the receiving device may have no previous information about an identity of electronic devices or a type of each of the electronic devices. The receiving device may also have no previous information about the EM emissions of each of the electronic devices, prior to receiving the EM emissions from the plurality of electronic devices.

The receiving device may cross-correlate the EM emissions received from a plurality of electronic devices over time. In some aspects, the receiving device may calculate a trend of the cross-correlated EM emissions over time. In some aspects, the receiving device may calculate a trend of the cross-correlated EM emissions using statistical analysis of the EM emissions over time. In some aspects, the receiving device may determine a trend characteristic of the calculated trend. In such aspects, the receiving device monitored the observed EM emissions to determine whether there is a difference of the cross correlated EM emissions over time compared to the determined trend or trend characteristic (i.e., a departure from the historically determined trend or trend characteristic).

The receiving device may determine whether an observed difference between the observed cross-correlated EM emissions and the calculated trend or trend characteristic indicates an anomaly in one or more of the plurality of electronic devices. When such an anomaly is recognized, the receiving device may take an action, such as alerting an operator, which may enable detection of future fault or failure of one or more of the electronic devices.

The receiving device may also use the cross-correlated EM emissions over time to determine at least one anomaly threshold. That is, with no prior information about electronic devices, the receiving device may analyze the cross-correlated EM emissions over time to determine, for example, a range of EM emissions or pattern of EM emissions that is characteristic of the cross-correlated EM emissions observed over time. Based on the cross-correlated EM emissions observations over time, the receiving device may determine at least one threshold that may serve to identify an anomalous deviation from the cross-correlated EM emissions over time. For example, the receiving device may use statistical analyses of cross-correlated EM emissions observed over time to determine average cross-correlated EM emissions and a typical variance or deviation from the average, and use some multiple of the determined variance or deviation as a threshold for concluding that an observed difference is an anomaly. In some aspects, when the receiving device determines that a difference of the cross-correlated EM emissions and a calculated trend of the cross-correlated EM emissions meets the at least one anomaly threshold, the receiving device may determine that the observed difference indicates that there is an anomaly in one or more of the plurality of electronic devices.

The various aspects enable a receiving device, such as a smartphone configured with EM receivers and processor-executable instructions to implement an aspect method, to recognize the potential for a malfunction or failure of an electronic device without requiring prior knowledge of the electronic devices being monitored or the nominal or abnormal behaviors of such electronic devices. In this manner, the various aspects enable a receiver device to alert a user (or provide EM data to service that can diagnose an operating condition of electronic devices based on the EM behavior) to anomalies that may indicate or portend an imminent or future malfunction or non-benign behavior. Since no information about the observed electronic devices is require, the various aspects enable an appropriately configured receiving device to passively observe EM emissions an alert a user to the potential for a malfunction or non-benign behavior without requiring the user to provide information about the electrical devices, thereby making the aspect methods easy to implement.

To perform the analysis of observed EM emissions, the receiving device may include a behavioral analysis system that may generate one or more EM emissions behavior vectors based on the EM emissions received from a plurality of electronic devices and compare such behavior vectors to EM emissions models to determine when there is a difference that may indicate an anomaly.

In various aspects the behavioral analysis system of the receiver device may generate the EM emissions models. In an aspect, by observing cross-correlated EM emissions over time, the behavioral analysis system may generate EM emissions models that are representative of normal observed behavior. Multiple EM emissions models may be generated based on observations over time, such as representative of particular times of day, days of week, seasons, EM sources, or other recognizable patterns of normal observed behavior. For example, different EM emissions models may be generated for morning, mid-day, evening, and nighttime hours, as well as separate models for such hours during the workweek and the weekend. Such EM emissions models may thus be reflective of cross-correlated EM emissions that are observed at certain times when a user's behavior or use of electronic devices leads to recognizable patterns in EM emissions.

With EM emissions models generated, behavioral analysis system of the receiver device may compare generated EM emissions vectors to one or more of the EM emissions models to recognize a difference that is indicative of an anomaly. In some aspects, the behavioral analysis system of the receiver device may continually refine EM emissions models based on observations over time, so that gradual changes in EM emissions by one or more devices do not eventually trigger an anomaly alert. However, trends in EM emissions cross-correlations may be useful for detecting when a particular device may be starting to fail. Thus, in some aspects the behavioral analysis system of the receiver device may calculate a trend of the cross-correlated EM emissions over time, such as based on observing changes over time in one or more EM emissions models. The behavioral analysis system of the receiver device may also analyze the evolution of EM emissions models to determine a trend characteristic of the cross-correlated EM emissions over time.

The behavioral analysis system of the receiver device may also analyze the EM emissions vectors over time to determine one or more anomaly thresholds that may be used for determining when a detected difference is indicative of an anomaly (e.g., compared to normal variability). The receiving device may compare the results of analyzing a cross-correlated EM emissions behavior vector to one or more EM emissions behavior models to the one or more anomaly thresholds to determine whether the differences indicate an anomaly in one or more of the plurality of electronic devices. In some aspects, the receiving device may take an action such as issue a notification to the user (e.g., visual audio, vibration, or a similar alert) in response to determining that the difference meets the at least one anomaly threshold.

The term “receiving device” is used herein to refer to a device that may be configured to receive EM emissions from a plurality of electronic devices, and may include any one or all of cellular telephones, smartphones, personal or mobile multi-media players, personal data assistants (PDAs), laptop computers, tablet computers, smartbooks, ultrabooks, palmtop computers, wireless electronic mail receivers, multimedia Internet enabled cellular telephones, wireless gaming controllers, and similar electronic devices which include a memory, a programmable processor, and EM sensors that may be configured to receive EM emissions from a plurality of electronic devices.

The terms “component,” “module,” “system,” and the like are used herein to refer to a computer-related entity, such as, but not limited to, hardware, firmware, a combination of hardware and software, software, or software in execution, which are configured to perform particular operations or functions. For example, a component may be, but is not limited to, a process running on a processor, a processor, an object, an executable, a thread of execution, a program, and/or a computer. By way of illustration, both an application running on a communication device and the communication device may be referred to as a component. One or more components may reside within a process and/or thread of execution and a component may be localized on one processor or core and/or distributed between two or more processors or cores. In addition, these components may execute from various non-transitory computer readable media having various instructions and/or data structures stored thereon. Components may communicate by way of local and/or remote processes, function or procedure calls, electronic signals, data packets, memory read/writes, and other known computer, processor, and/or process related communication methodologies.

A behavioral analysis system may include a behavior observer module and a behavior analyzer module. The behavior observer module may be configured to receive data from a radio frequency (RF) receiver or receivers configured to pick up EM emissions from a variety of electronic devices. The behavior observer module may translate the data received from the RF receiver or receivers into a plurality of values characterizing the spectrum of EM emissions received from a plurality of electronic devices during an observation window. The behavior observer module may store the collected EM emissions information in a memory (e.g., in a log file, etc.) in the form of EM emissions behavior vectors. For example, an EM emissions behavior vector may include a number of values (e.g., in a vector format) that are indicative of observed power levels and time-based variability at a number of different frequencies. Because the EM emissions of most electronic devices varies with time (e.g., at the frequency of the power source, at the frequency of major electronic operations, and/or at the frequency of a rotational element such as a rotor), an EM emissions behavior vector may include time-varying characteristic information based on EM emissions received over an observation window (e.g., one second, five seconds, etc.). Thus, EM emissions behavior vectors may be a compact data format for characterizing the broad spectrum of time-varying EM emissions received from an unknown number of electrical devices.

Each EM emissions behavior vector may be a data structure or an information structure that includes or encapsulates one or more features (e.g., observed EM frequency bands) of the EM emissions. An EM emissions behavior vector may include an abstract number or symbol that represents all or a portion of EM emissions data observed by the receiving device (i.e., a feature). Each feature may be associated with a data type that identifies a range of possible values, operations that may be performed on those values, the meanings of the values, and other similar information. The data type may be used by the receiving device to determine how the corresponding feature (or feature value) should be measured, analyzed, weighted, or used.

As described above, in various aspects the behavioral analysis system may generate one or more EM emissions behavior classifier models using the received EM emissions. Various machine learning methods may be used to generate such behavior classifier models. For example, in an aspect the behavioral analysis system may analyze EM behavior vectors stored over time to identify average, upper, and/or lower bounds of power levels in each of a number of frequency bands, as well as average, upper, and/or lower bounds in variability of power levels in each of the frequency bands, and use such results to generate a behavior classifier model. As another example, in an aspect the behavioral analysis system may analyze EM behavior vectors stored over time to identify cross-correlations in power level and/or time-varying behavior across two or more frequency bands that are usually present within EM emissions behavior vectors, and use such results to generate an EM emissions behavior classifier model. Such EM emissions behavior classifier model may be generated so that an EM emissions behavior vector can be analyzed using the classifier model through a simple vector or arithmetic operation. Thus, EM emissions behavior classifier models provide processor-efficient mechanism for recognizing anomalies in received EM emissions.

In an aspect, the receiving device may be configured to develop and store classifier models of cross-correlated EM emissions over time. A model of cross-correlated EM emissions may identify one or more features of observable cross-correlated EM emissions from the plurality of electronic devices. In some aspects, models of the cross-correlated EM emissions may be stored in a cloud server or network, shared across a large number of devices, sent to the receiving device periodically or on demand, and customized in the device based on the available sensors of the receiving device. One or more models of the cross-correlated EM emissions may be, or may be included, in a classifier model. In some aspects, the behavioral analysis system may adjust the size of a behavior vector to change the granularity of features extracted from the real-time data.

An EM emissions behavior classifier model may be a behavior model that includes data, entries, decision nodes, decision criteria, and/or information structures that may be used by a device processor to quickly and efficiently test or evaluate features (e.g., aspects of the EM emissions or the cross-correlated EM emissions) of observed real-time EM emissions data.

In some aspects, the behavioral analysis system may compare the generated EM emissions behavior vectors to a plurality of EM emissions behavior classifier models to determine a trend of the cross-correlated EM emissions over time. In some aspects, the behavioral analysis system may determine a trend characteristic of the determined trend.

The behavioral analysis system may also determine at least one anomaly threshold based on the cross-correlated EM emissions of the plurality of electronic devices over time. The behavioral analysis system may also determine at least one difference of the cross-correlated EM emissions in the calculated trend. Based on a comparison of the generated EM emissions behavior vectors to the one or more EM classifier models and to the at least one anomaly threshold, the behavioral analysis may determine that a difference of the cross-correlated EM emissions and the calculated trend indicates an anomaly in one or more of the plurality of electronic devices.

The behavior analysis system may include processes, daemons, modules, or sub-systems (herein collectively referred to as a “module”) to observe in real-time EM emissions of electronic devices, extract one or more features of the EM emissions data, and to analyze (e.g., cross-correlate) the extracted one or more features of the EM emissions of the plurality of electronic devices. An observer module may be configured to collect EM emissions from the instrumented components, and communicate (e.g., via a memory write operation, function call, etc.) the collected EM emissions data to the feature extractor module.

The feature extractor module may use the collected EM emissions data to generate EM emissions behavior vectors that each represent or characterize many or all of the received EM emissions. The feature extractor module may communicate (e.g., via a memory write operation, function call, etc.) the generated behavior vectors to an analyzer module.

The analyzer module may apply the behavior vectors to classifier models to generate analysis results, and use the analysis results to cross-correlated EM emissions over time, calculated trend of the cross-correlated EM emissions over time, determine a trend characteristic of the cross-correlated EM emissions over time, determine at least one anomaly threshold based on the cross-correlated EM emissions of the plurality of electronic devices over time, identified difference of the cross-correlated EM emissions and the calculated trend (or the determined trend characteristic), determine whether an identified difference meets and anomaly threshold, and in response to determining that the difference meets the threshold, determine that the difference of the cross correlated EM emissions of the calculated trend indicates an anomaly in one or more of the plurality of electronic devices.

In an aspect, the receiving device may be configured to generate a behavior vector of size “n” that maps the observer real-time data into an n-dimensional space. Each number or symbol in the behavior vector (i.e., each of the “n” values stored by the vector) may represent the value of a feature. The receiving device may analyze the behavior vector (e.g., by applying the behavior vector to a model of various environments corresponding with various real-time data.) to characterize and/or cross-correlate the EM emissions of the plurality of electronic devices. In some aspects, the receiving device may also aggregate the behavior scores of all observed EM emissions data, for example, into an average behavior score, a weighted average behavior score, or another aggregation. In some aspects, one or more weights may be selected based on the feature of the real-time data.

A classifier model may include a larger or smaller data set, the size of which may affect an amount of processing required to apply a behavior vector to the classifier model. For example, a “full” classifier model may be a large and robust data model that may be generated as a function of a large training dataset, and which may include, for example, thousands of features and billions of entries. As another example, a “lean” classifier model may be a more focused data model that is generated from a reduced dataset that includes or prioritizes tests on the features/entries that are most relevant for determining and characterizing a particular receiving device's RF environment using the sensors and software available on that particular receiving device. In some aspects, the behavioral analysis system may change the robustness and/or size of a classifier model used to analyze a behavior vector.

A local classifier model may be a lean classifier model that is generated in the receiving device. By generating classifier models in the receiving device in which the models are used, the various aspects allow the receiving device to accurately identify the specific features that are most important in determining, characterizing, and cross-correlating EM emissions received by particular receiving device. These aspects also allow the receiving device to accurately prioritize the features in the classifier models in accordance with their relative importance to classifying behaviors in that specific device.

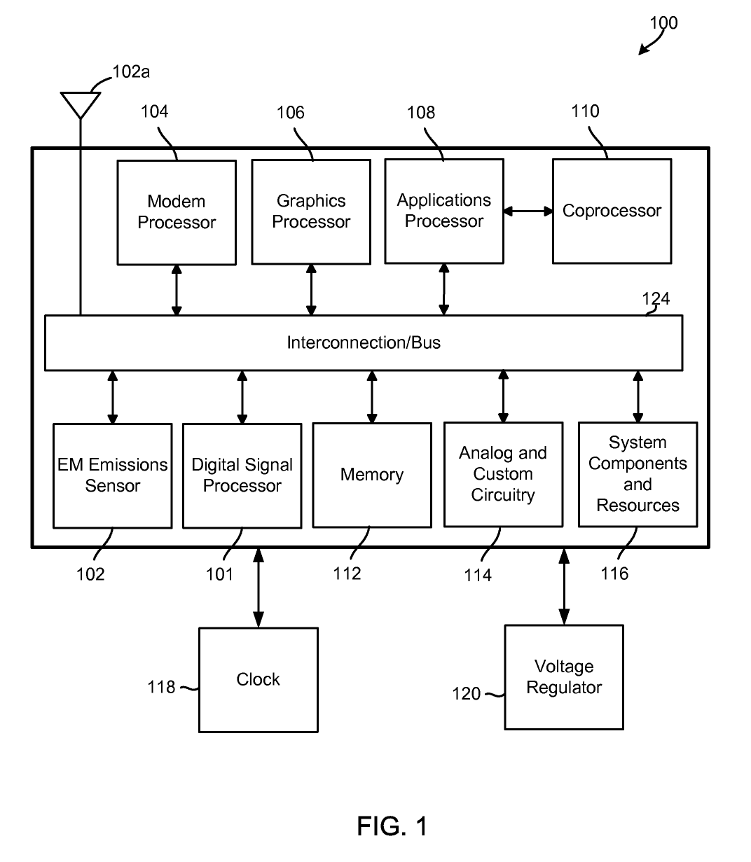

The various aspects may be implemented in a number of different receiving devices, including single processor and multiprocessor systems, and a system-on-chip (SOC). FIG. 1 is an architectural diagram illustrating an example SOC 100 architecture that may be used in receiving devices implementing the various aspects. The SOC 100 may include a number of heterogeneous processors, such as a digital signal processor (DSP) 101, a modem processor 104, a graphics processor 106, and an application processor 108. The SOC 100 may also include one or more coprocessors 110 (e.g., vector co-processor) connected to one or more of the heterogeneous processors 101, 104, 106, 108. Each processor 101, 104, 106, 108, 110 may include one or more cores, and each processor/core may perform operations independent of the other processors/cores. For example, the SOC 100 may include a processor that executes a first type of operating system (e.g., FreeBSD, LINUX, OS X, etc.) and a processor that executes a second type of operating system (e.g., Microsoft Windows 8).

The SOC 100 may include one or more EM emissions sensor 102 that may receive EM emissions from a plurality of electronic devices. The EM emissions sensor 102 may receive signals from an antenna 102a or similar device for receiving the EM emissions of the plurality of electronic devices. In some aspects the EM emissions sensor 102 may be a dedicated RF receiver configured to receive EM emissions from a plurality of electronic devices. In some aspects the EM emissions sensor 102 may be an RF transceiver suitable for supporting wireless communications of one or more technologies (e.g., WiFi, Bluetooth, and/or cellular network, such as WCDMA, GSM, UMTS, etc.) that has additional capabilities to receive EM emissions.

Each processor 101, 104, 106, 108, 110 may include one or more cores, and each processor/core may perform operations related to the reception and/or processing of EM emissions from the plurality of electronics devices, which operations may be independent of and/or coordinated with operations of the other processors/cores. For example, in some aspects, one processor/core (e.g., the modem processor 104) may receive the EM emissions, and another processor/core (e.g., the applications processor 108) may perform a characterization, correlation, cross-correlation, and/or other processing of the received EM emissions.

The system components 116 and custom circuitry 114 may include circuitry to interface with peripheral devices, such as cameras, electronic displays, wireless communication devices, external memory chips, etc. The processors 101, 104, 106, and 108 may be interconnected to one or more memory elements 112, system components, and resources 116 and custom circuitry 114 via an interconnection/bus module 124, which may include an array of reconfigurable logic gates and/or implement a bus architecture (e.g., CoreConnect, AMBA, etc.). Communications may be provided by advanced interconnects, such as high performance networks-on chip (NoCs).

The SOC 100 may further include an input/output module (not illustrated) for communicating with resources external to the SOC, such as a clock 118 and a voltage regulator 120. Resources external to the SOC (e.g., clock 118, voltage regulator 120) may be shared by two or more of the internal SOC processors/cores (e.g., DSP 101, modem processor 104, graphics processor 106, applications processor 108, etc.).

In addition to the SOC 100 discussed above, the various aspects may be implemented in a wide variety of computing systems, which may include a single processor, multiple processors, multicore processors, or any combination thereof.

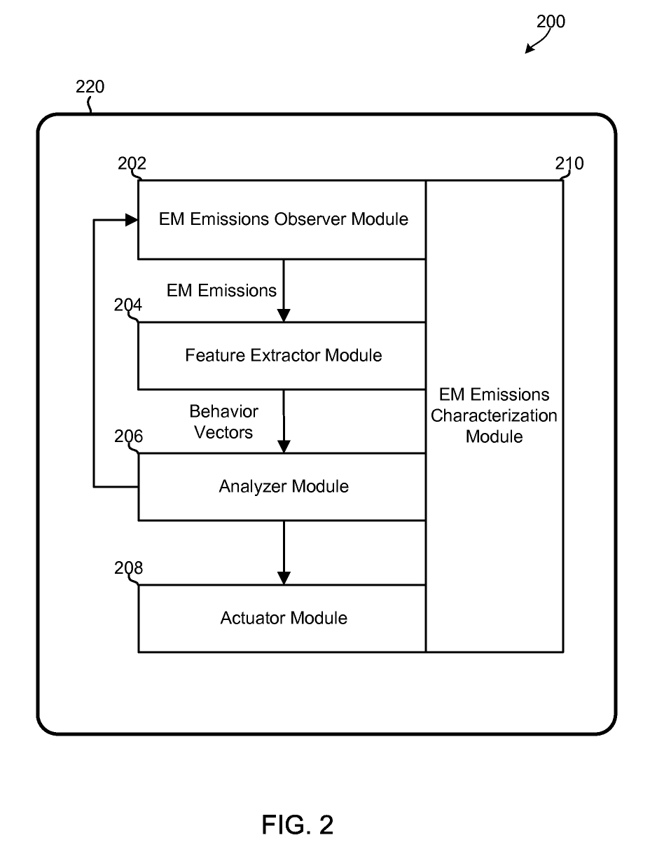

FIG. 2 illustrates example logical components and information flows in an aspect receiving device that includes an EM emissions characterization system 200 configured to use behavioral analysis techniques to characterize EM emissions of the plurality of electronic devices in accordance with the various aspects. In the example illustrated in FIG. 2, the receiving device may be a mobile device 220 that includes a device processor (e.g., a mobile device processor) configured with executable instruction modules that include an EM emissions observer module 202, a feature extractor module 204, an analyzer module 206, an actuator module 208, and an EM emissions characterization module 210.

In various aspects, all or portions of the EM emissions characterization module 210 may be implemented as part of the EM emissions observer module 202, the feature extractor module 204, the analyzer module 206, or the actuator module 208. Each of the modules 202-210 may be a thread, process, daemon, module, sub-system, or component that is implemented in software, hardware, or a combination thereof. In various aspects, the modules 202-210 may be implemented within parts of the operating system (e.g., within the kernel, in the kernel space, in the user space, etc.), within separate programs or applications, in specialized hardware buffers or processors, or any combination thereof. In an aspect, one or more of the modules 202-210 may be implemented as software instructions executing on one or more processors of the receiving device 220.

The EM emissions characterization module 210 may be configured to cross-correlate and characterize the EM emissions received by the of the receiving device, calculate a trend of the cross-correlated EM emissions over time, determine a trend characteristic of the calculated trend, identify a difference of the cross-correlated EM emissions and the calculated trend and/or the determined trend characteristic, determine at least one anomaly threshold based on the cross-correlated EM emissions of the plurality of electronic devices over time, determine whether the difference of the cross-correlated EM emissions and the calculated trend (or the trend characteristic) meets the at least one anomaly threshold, and in response to determining that the difference meets the at least one threshold, determining that the difference indicates an anomaly in one or more of the plurality of electronic devices.

The EM emissions observer module 202 may be configured to monitor the received EM emissions of the plurality of electronic devices and EM emissions sensor (e.g., the EM emissions sensor 102 in FIG. 1). The EM emissions observer module 202 may be configured to monitor real-time data associated with the EM emissions received by a receiving device (e.g., a receiving device including the SOC 100 illustrated in FIG. 1). The SOC 100 may also include hardware and/or software components suitable for collecting EM emissions data of the plurality of electronic devices.

To reduce the number of factors monitored to a manageable level, in an aspect, the EM emissions observer module 202 may be configured to perform coarse observations by monitoring/observing an initial set of EM emissions behaviors or factors that are a small subset of all EM emissions. In some aspects, the EM emissions observer module 202 may receive the initial set of behaviors and/or factors from a server and/or a component in a cloud service or network. In some aspects, the initial set of behaviors/factors may be specified in machine learning classifier models.

The EM emissions observer module 202 may communicate (e.g., via a memory write operation, function call, etc.) the collected real-time EM emissions data to the feature extractor module 204. The feature extractor module 204 may be configured to receive or retrieve the collected EM emissions data and use this information to generate one or more behavior vectors. Each behavior vector may succinctly describe the observed EM emissions data in a value or vector data-structure. In some aspects, the vector data-structure may include a series of numbers, each of which signifies a partial or complete representation of the real-time data collected by the EM emissions observer module 202.

In some aspects, the feature extractor module 204 may be configured to generate the behavior vectors so that they function as an identifier that enables the behavioral analysis system (e.g., the analyzer module 206) to quickly characterizing cross-correlate the EM emissions over time. In an aspect, the feature extractor module 204 may be configured to generate behavior vectors of size “n,” each of which maps the real-time EM emissions data into an n-dimensional space. In an aspect, the feature extractor module 204 may be configured to generate the behavior vectors to include information that may be input to a feature/decision node in the EM emissions characterization module to generate an answer to a query regarding one or more features of the EM emissions data to characterize and cross-correlate the EM emissions of the plurality of electronic devices received by the receiving device.

The feature extractor module 204 may communicate (e.g., via a memory write operation, function call, etc.) the generated behavior vectors to the analyzer module 206. The analyzer module 206 may be configured to apply the behavior vectors to classifier modules to analyze the EM emissions. In addition, the behavior analyzer module 206 may be configured to apply the behavior vectors to classifier modules to characterize and cross-correlate the EM emissions.

Each classifier model may be a behavior model that includes data and/or information structures (e.g., feature vectors, behavior vectors, component lists, etc.) that may be used by a receiving device processor to evaluate a specific feature or aspect of the received EM emissions. Each classifier model may also include decision criteria for monitoring a number of features, factors, data points, conditions, behaviors, trends, etc. (herein collectively “features”). The classifier models may be preinstalled on the receiving device, downloaded or received from a network server, generated in the receiving device, or any combination thereof. The classifier models may also be generated by using crowd sourcing solutions, behavior modeling techniques, machine learning algorithms, or other methods of generating classifier models.

Each classifier model may be a full classifier model or a lean classifier model. A full classifier model may be a robust data model that is generated as a function of a large training dataset, which may include thousands of features and billions of entries. A lean classifier model may be a more focused data model that is generated from a reduced dataset that analyzes or tests only the features/entries that are most relevant for evaluating real-time data. A lean classifier model may be used to analyze a behavior vector that includes a subset of the total number of features and behaviors that could be observed in a receiving device. As an example, a device processor may be may be configured to receive a full classifier model from a network server, generate a lean classifier model in the mobile device based on the full classifier, and use the locally generated lean classifier model to evaluate real-time EM emissions data collected in a behavior vector.

A locally generated lean classifier model is a lean classifier model that is generated in the receiving device. That is, receiving devices may be highly configurable and complex systems, and the features that may be extracted from real-time EM emissions data may be different in each device. Further, a different combination of features may be monitored and/or analyzed in each device in order for that device to quickly and efficiently characterize and/or cross-correlate the received EM emissions. The precise combination of features that require monitoring and analysis, and the relative priority or importance of each feature or feature combination, may often only be determined using information obtained from the specific device that is receiving and cross-correlating the EM emissions. For these and other reasons, various aspects may generate classifier models in the mobile device in which the models are used.

Local classifier models may enable the device processor to accurately identify those specific features that are most important for characterizing and cross-correlating EM emissions received by the receiving device. The local classifier models may also allow the device processor to prioritize the features that are tested or evaluated in accordance with their relative importance to characterizing and cross-correlating the EM emissions.

In some aspects, a device-specific classifier model may be used, which is a classifier model that includes a focused data model that includes/tests only receiving device-specific features/entries that are determined to be most relevant to and characterizing and cross-correlating the EM emissions. By dynamically generating device-specific classifier models locally in the mobile device, the various aspects allow the device processor to focus monitoring and analysis operations on a small number of features that are most important, applicable, and/or relevant for characterizing and cross-correlating the EM emissions received by that specific receiving device.

In an aspect, the analyzer module 206 may be configured to adjust the granularity or level of detail of the features of the EM emissions data that the analyzer module evaluates, in particular when an analysis features of real-time EM emissions data is inconclusive. For example, the analyzer module 206 may be configured to notify the real-time data observer module 202 in response to determining that it cannot characterize and/or cross-correlate the received EM emissions based on a current set of features of real-time EM emissions data provided to the analyzer module (i.e., cannot characterize and/or cross-correlate the EM emissions to a threshold level of certainty). In response, the EM emissions observer module 202 may change the monitored and factors or behaviors and/or adjust the granularity of its observations (i.e., the level of detail and/or the frequency at which EM emissions data is observed) based on a notification sent from the analyzer module 206 (e.g., a notification based on results of the analysis of the real-time data features).

The EM emissions observer module may also generate or collect new or additional EM emissions data, and send the new/additional EM emissions data to the feature extractor module 204 and the analyzer module 206 for further analysis/classification. Such feedback communications between the EM emissions observer module 202 and the analyzer module 206 may enable the receiving device 220 to recursively increase the granularity of the observations (i.e., make more detailed and/or more frequent observations) or change EM emissions data that are observed until the analyzer module can properly characterize and/or cross-correlate the EM emissions up to a threshold level of reliability. Such feedback communications may also enable the receiving device 220 to adjust or modify the behavior vectors and classifier models without consuming an excessive amount of the receiving device's processing, memory, or energy resources.

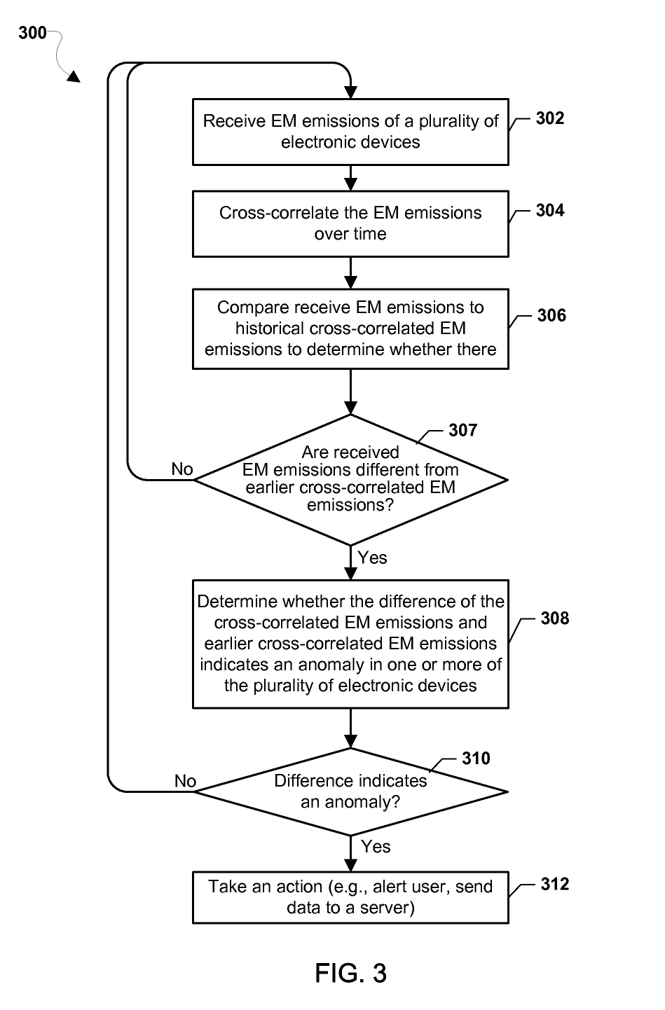

FIG. 3 illustrates a method 300 of detecting anomalous EM emissions from among a plurality of electronic devices in accordance with the various aspects. The method 300 may be performed by one or more processing cores or device processors of a mobile or resource constrained receiving device, such as a processor on a system-on-chip (e.g., processors 101, 104, 106, and 108 on the SOC 100 illustrated in FIG. 1) or any similar processor, and may employ a behavioral analysis system to characterize and cross-correlate EM emissions (e.g., the EM emissions characterization system 200 in FIG. 2). In some aspects, different processors of a receiving device may perform operations related to the reception and/or processing of EM emissions from a plurality of electronics devices, which operations may be independent of and/or coordinated with operations of the other processors of the receiving device. For example, in some aspects, one processor, such as the modem processor 104, may receive EM emissions, another processor, such as the digital signal processor 101, may perform a characterization, correlation, cross-correlation, and/or other processing of the received EM emissions, and another processor, such as the applications processor 108, may determine an anomaly in one or more EM processed (e.g., characterized, correlated, or cross-correlated) EM emissions.

In block 302, a device processor may receive EM emissions of the plurality of electronic devices using an EM emissions sensor of the receiving device. Detected EM emissions may include frequencies, harmonics, signal strengths, and changes to any of the foregoing over time. The receiving device (i.e., the device processor) may have no prior information about the electronic devices from which it receives EM emissions. For example, the receiving device may have no previous information about an identity of electronic devices or a type of each of the electronic devices. The receiving device may also have no previous information about the EM emissions of each of the electronic devices, prior to receiving the EM emissions from the plurality of electronic devices.

In block 304, the device processor may cross-correlate the EM emissions over time. For example, the device processor may receive and cross-correlate one or more of frequency emissions, frequency harmonic(s) emissions, signal strengths, and other receivable data of the EM emissions of the plurality of electronic devices. The device processor may also cross-correlate one or more signal analyses, such as a discrete Fourier transform or fast Fourier transform of one or more characteristics of the received EM emissions of the plurality of electronic devices.

In block 306, the device processor may compare the observed cross-correlated EM emissions to earlier cross-correlated EM emissions, and in determination block 307 the processor may determine whether the received EM emissions or emissions behaviors are different from earlier cross-correlated EM emissions or emissions behavior. In some aspects this comparison and determination may be made by applying an EM emissions behavior classifier model to an EM emissions behavior vector generated from observed EM emissions as described above. From the stored cross-correlated EM emissions data (e.g., stored as behavior vectors as described above), the device processor may determine characteristic cross-correlated behaviors of the plurality of electronic devices emitting EM radiation, and may determine the pattern, trend, or another aspect of the cross correlated behaviors of electronic devices over time. Further, the device processor may identify a difference, such as a deviation from a determined pattern are trend, of currently characterized in cross-correlated EM emissions as compared to earlier cross-correlated EM emissions. In response to determining that the received EM emissions or emissions behaviors are not substantially different from earlier cross-correlated EM emissions or emissions behavior (i.e., determination block 307=“No”), the device processor may continue to receive and observe EM emissions in block 302.

In response to determining that the received EM emissions or emissions behaviors are different from earlier cross-correlated EM emissions or emissions behavior (i.e., determination block 307=“Yes”), the device processor may determine whether the difference of the cross co-correlated EM emissions in the earlier cross-correlated EM emissions indicates an anomaly in one or more of the plurality of electronic devices in block 308 and determination block 310. Since the electronic devices are within proximity of the receiving device, the electronic devices are most likely to be within sufficient proximity to each other that each of their EM emissions may affect the EM emissions of the other electronic devices. Anomalous behavior by one or more of the electronic devices may not only affect its EM emissions, but it may also affect the EM emissions of one or more of the other proximate electronic devices. Thus, a difference in the cross-correlated EM emissions of the plurality of electronic devices may indicate an anomaly in one or more of the electronic devices. The anomaly may be the result of, or an indication of, a changed behavior, such as wear and tear of an electronic device over time, a change in behavior of a component of an electronic device, or another similar indication that may be a harbinger of degraded performance or failure of a component of one or more of the plurality of electronic devices.

In some aspects, this determination in blocks 308 and 310 may be made by applying an EM emissions behavior classifier model to the EM emissions behavior vector generated from observed EM emissions as described above. The EM emissions behavior classifier model used to determine whether a difference indicates an anomaly may be different from the EM emissions behavior classifier model used in blocks 306 and 307 to determine whether there is a difference between observed EM emissions and historical cross-correlated EM emissions.

In response to determining that the differences between the cross-correlated EM emissions and earlier cross-correlated EM emissions data do not indicate an anomaly (i.e., determination block 310=“No”), the device processor may continue to receive additional EM emissions of the plurality of electronic devices in block 302.

In response to determining that the differences between the cross-correlated EM emissions and earlier cross-correlated EM emissions data do indicate an anomaly (i.e., determination block 310=“Yes”), the device processor may take an action, such as to issue an alert to the user, in block 312. Such an alert to the user may be in the form of a visual display, tone, vibration, message, email, or any combination thereof configured to inform the user about the anomaly, such as a warning that some electrical device may be malfunctioning or about to malfunction. In some aspects, the action taken in block 312 may be to forward the received EM emissions data (e.g., an EM emissions behavior vector) to another computing device, such as a remote server, for analysis. Such aspects may enable another computing device with access to normal and abnormal EM emissions information to use the EM emissions data gathered by the receiver device to diagnose the cause of the anomaly, and potentially inform the user or a service vendor (e.g., via an email) about the cause of the anomaly. This may enable a malfunctioning electrical device to be recognized and service promptly without requiring the receiving device to be configured with diagnostic data that would be impractical in the limited memory of typical devices that may be configured as a receiver device (e.g., smartphones).

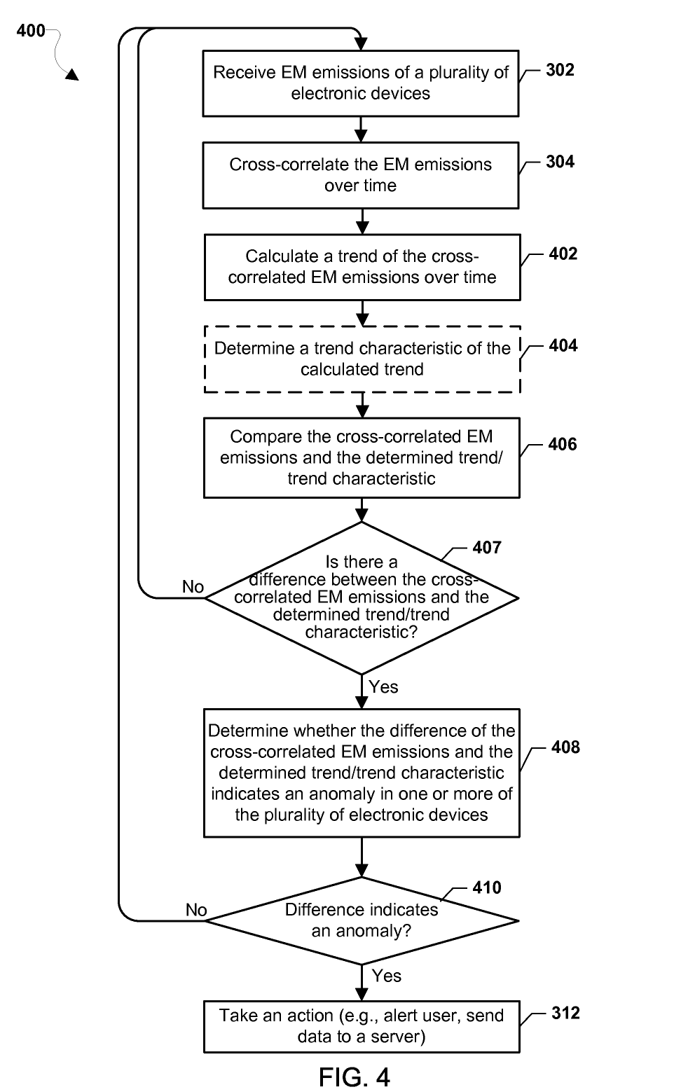

FIG. 4 illustrates a method 400 of detecting anomalous EM emissions from among a plurality of electronic devices in accordance with the various aspects. The method 400 may be performed by one or more processing cores or device processors of a mobile or resource constrained receiving device, such as a processor on a system-on-chip (e.g., processors 101, 104, 106, and 108 on the SOC 100 illustrated in FIG. 1) or any similar processor, and may employ a behavioral analysis system to characterize and cross-correlate received EM emissions (e.g., the EM emissions characterization system 200 in FIG. 2). In some aspects, different processors of a receiving device may perform operations related to the reception and/or processing of EM emissions from a plurality of electronics devices, which operations may be independent of and/or coordinated with operations of the other processors of the receiving device. For example, in some aspects, one processor, such as the modem processor 104, may receive EM emissions, another processor, such as the digital signal processor 101, may perform a characterization, correlation, cross-correlation, and/or other processing of the received EM emissions, and another processor, such as the applications processor 108, may determine an anomaly in one or more EM processed (e.g., characterized, correlated, or cross-correlated) EM emissions.

In some aspects, the device processor may perform operations in blocks 302 and 304 similar to those described above with reference to blocks 302 and 304 of the method 300.

In block 402, the device processor may calculate a trend of the cross-correlated EM emissions over time. The calculated trend may indicate a pattern of behavior of the plurality of electronic devices as may be indicated by the cross-correlated EM emissions over time. The device processor may calculate the trend using one or more statistical analyses of the EM emissions data or cross-correlated EM emissions, or by observing changes over time in EM emissions behavior classifier models generated by receiver device as described above.

In optional block 404, the device processor may determine a trend characteristic of the calculated trend. In some aspects, the trend characteristic may include one or more of a lock-step trend, a time-shifted trend, and a substantially uncorrelated trend. In other words, the trend characteristic may provide an indication of the closeness of the cross-correlation of the EM emissions of the plurality of electronic devices over time.

In block 406, the device processor may compare the cross-correlated EM emissions of the plurality of electronic devices to the calculated trend and/or the determine trend characteristic, and in determination block 407 the processor may determine whether there is a difference between the cross-correlated EM emissions and the determined trend or trend characteristic. In some aspects, the device processor may compare stored cross-correlated EM emissions with the calculated trend and/or with the determined trend characteristic. Further, the device processor may identify a difference, such as a deviation from the calculated trend and/or the determined trend characteristic. In some aspects this comparison and determination may be made by applying an EM emissions behavior classifier model to an EM emissions behavior vector generated from observed EM emissions as described above. In response to determining that there is not a significant difference between the cross-correlated EM emissions and the determined trend or trend characteristic (i.e., determination block 407=“No”), the processor may continue to receive and observe EM emissions of a plurality of electronic devices in block 302.

In response to determining that there is a significant difference between the cross-correlated EM emissions and the determined trend or trend characteristic (i.e., determination block 407=“Yes”), the device processor may determine whether the difference between the cross-correlated EM emissions and calculated trend and/or the determined trend characteristic indicates an anomaly in one or more of the plurality of electronic devices in block 408 and determination block 410. In some aspects, this determination in blocks 408 and 410 may be made by applying an EM emissions behavior classifier model to the EM emissions behavior vector generated from observed EM emissions as described above. The EM emissions behavior classifier model used to determine whether a difference indicates an anomaly may be different from the EM emissions behavior classifier model used in blocks 406 and 407 to determine whether there is a difference between observed EM emissions and historical cross-correlated EM emissions.

In response to determining that the differences between the cross-correlated EM emissions and calculated trend and/or the determined trend characteristic indicates do not indicate an anomaly (i.e., determination block 410=“No”), the device processor may continue to receive additional EM emissions of the plurality of electronic devices in block 302.

In response to determining that the differences between the cross-correlated EM emissions and calculated trend and/or the determined trend characteristic indicates an anomaly (i.e., determination block 410=“Yes”), the device processor may take an action in block 312 as described above, such as to issue an alert to the user or send EM emissions data to a remote server for analysis.

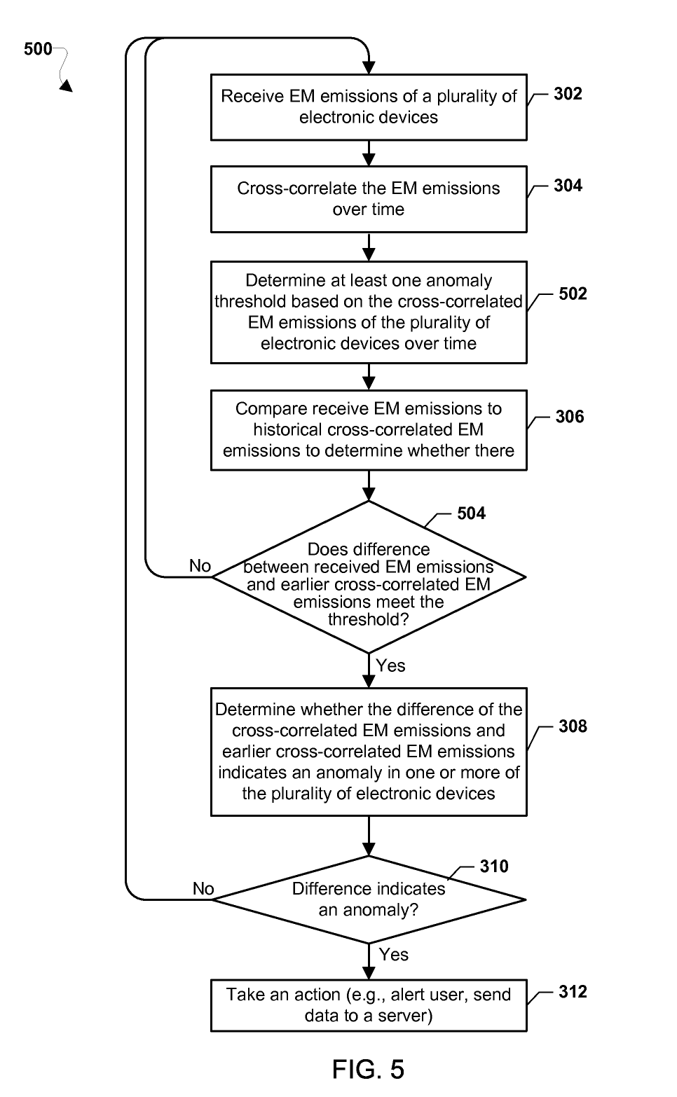

FIG. 5 illustrates an example method 500 of detecting anomalous EM emissions from among a plurality of electronic devices in accordance with the various aspects. The method 500 may be performed by one or more processing cores or device processors of a mobile or resource constrained receiving device, such as a processor on a system-on-chip (e.g., processors 101, 104, 106, and 108 on the SOC 100 illustrated in FIG. 1) or any similar processor, and may employ a behavioral analysis system to characterize and cross-correlate received EM emissions (e.g., the EM emissions characterization system 200 in FIG. 2). In some aspects, different processors of a receiving device may perform operations related to the reception and/or processing of EM emissions from a plurality of electronics devices, which operations may be independent of and/or coordinated with operations of the other processors of the receiving device. For example, in some aspects, one processor, such as the modem processor 104, may receive EM emissions, another processor, such as the digital signal processor 101, may perform a characterization, correlation, cross-correlation, and/or other processing of the received EM emissions, and another processor, such as the applications processor 108, may determine an anomaly in one or more EM processed (e.g., characterized, correlated, or cross-correlated) EM emissions.

In some aspects, the device processor may perform operations in blocks 302, 304, 306, 308, 310 and 312 similar to those described with reference to like numbered blocks of the method 300. In block 302, a device processor may receive EM emissions of the plurality of electronic devices using an EM emissions sensor of the receiving device, and in block 304, the device processor may cross-correlate the EM emissions over time.

In block 502, the device processor may determine at least one anomaly threshold based on the cross-correlated EM emissions of the plurality of electronic devices over time. The receiving device may, with no prior information about electronic devices, analyze the cross-correlated EM emissions over time, and may determine, for example, a range of EM emissions, or pattern of cross-correlated EM emissions, that is characteristic of the behavior of electronic devices over time as observed by the receiver device as described above. Based on the cross-correlated EM emissions over time, the receiving device may determine at least one threshold that may serve to identify an anomalous deviation from the cross-correlated EM emissions over time. In some aspects, the device processor may determine that a difference of the cross-correlated EM emissions and a calculated trend meets the at least one anomaly threshold, and in response to determining that the difference meets the threshold, the receiving device may determine that the difference of the cross-correlated EM emissions and the calculated trend indicates an anomaly in one or more of the plurality of electronic devices. In some aspects, the device processor may determine that a difference of the cross-correlated EM emissions and a determined trend characteristic meets the at least one anomaly threshold, and in response to determining that the difference meets the threshold, the receiving device may determine that the difference of the cross-correlated EM emissions and the determined trend characteristic indicates an anomaly in one or more of the plurality of electronic devices. The device processor may determine a variety of anomaly thresholds such as a deviation from a frequency range, a deviation from a frequency range of her time, a deviation in a frequency harmonic, a deviation in a range or production of frequency harmonic(s) over time, a deviation in one or more signal strengths, and a deviation in a signal strength of the cross-correlated EM emissions. Other anomaly thresholds are also possible.

In block 306, the device processor may compare the cross-correlated EM emissions from earlier cross-correlated EM emissions. In some aspects, the device processor may identify a difference of the cross-correlated EM emissions from a calculated trend of the cross-correlated emissions over time. In some aspects, the calculated trend may be a calculated trend of earlier cross-correlated EM emissions. In some aspects, the device processor may identify a difference of the cross-correlated EM emissions from a trend characteristic of the calculated trend.

In determination block 504, the device processor may determine whether the identified difference meets the at least one anomaly threshold identified in block 502. In some aspects this comparison and determination may be made by applying an EM emissions behavior classifier model to an EM emissions behavior vector generated from observed EM emissions as described above. In response to determining that the difference does not meet the threshold (i.e., determination block 504=“No”), the device processor may continue to receive additional EM emissions of the plurality of electronic devices in block 302.

In response to determining that the difference meets the threshold (i.e., determination block 504=“Yes”), the device processor may determine whether the difference of the cross-correlated EM emissions from the earlier cross-correlated EM emissions indicates an anomaly in one or more of the plurality of electronic devices in block 308 and determination block 310. In some aspects, this determination in blocks 308 and 310 may be made by applying an EM emissions behavior classifier model to the EM emissions behavior vector generated from observed EM emissions as described above. The EM emissions behavior classifier model used to determine whether a difference indicates an anomaly may be different from the EM emissions behavior classifier model used in blocks 306 and 307 to determine whether there is a difference between observed EM emissions and historical cross-correlated EM emissions.

In response to determining that the differences between the cross-correlated EM emissions and earlier cross-correlated EM emissions data do not indicate an anomaly (i.e., determination block 310=“No”), the device processor may continue to receive additional EM emissions of the plurality of electronic devices in block 302.

In response to determining that the differences between the cross-correlated EM emissions and earlier cross-correlated EM emissions data do indicate an anomaly (i.e., determination block 310=“Yes”), the device processor may take an action in block 312, such as to issue an alert to the user or transmitting EM emissions data to a remote server for analysis.

The various aspects improve upon existing solutions by using behavior analysis and/or machine learning techniques to monitor and analyze real-time EM emissions data from a plurality of electronic devices to recognize a change in behavior of one or more electronic devices within a plurality of devices that may indicate an actual or potential degradation of performance or failure of the electronic device(s). The use of behavior analysis or machine learning techniques is important because modern receiving devices are highly configurable and complex systems, and the relevant and/or available data or extractable features may be different in each receiving device. Further, different combinations of device features/factors may require an analysis in each device in order for that device to determine an anomaly that may indicate actual or potential degradation of performance or failure of an electronic device. In some cases, the precise combination of data and/or features that a receiving device may monitor may be determined using information obtained from the specific receiving device in which the EM emissions data is monitored in real-time. For these and other reasons, existing solutions are not adequate for monitoring real-time EM emissions data, cross-correlating EM emissions over time, identifying the difference of the cross-correlated EM emissions from earlier cross-correlated EM emissions, and determining that the difference may indicate an anomaly in one or more of a plurality of electronic devices, and without consuming a significant amount of the receiving device's processing, memory, or power resources.

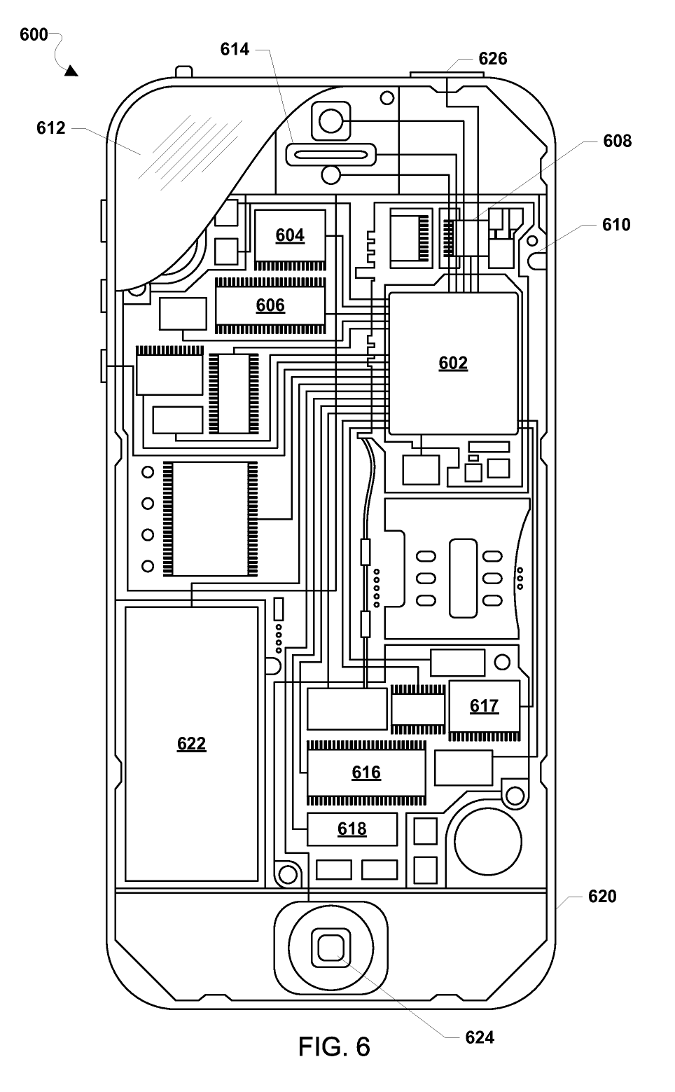

The various aspects, including the aspects discussed above with reference to FIGS. 1-5, may be implemented on a variety of receiving devices, an example of which is the mobile communication device 600 illustrated in FIG. 6. The mobile receiving device 600 may include a processor 602 coupled to internal memory 604, a display 612, and to a speaker 614. The processor 602 may be one or more multi-core integrated circuits designated for general or specific processing tasks. The internal memory 604 may be volatile or non-volatile memory, and may also be secure and/or encrypted memory, or unsecure and/or unencrypted memory, or any combination thereof. The mobile communication device 600 may have two or more radio signal transceivers 608 (e.g., Peanut, Bluetooth, Zigbee, Wi-Fi, RF radio, etc.) and antennae 610 for sending and receiving communications, coupled to each other and to the processor 602. Additionally, the mobile communication device 600 may include an antenna 610 for sending and receiving electromagnetic radiation that may be connected to a wireless data link and/or transceiver 608 coupled to the processor 602. The mobile communication device 600 may include one or more cellular network wireless modem chip(s) 616 coupled to the processor 602 and the antennae 610 that enable communications via two or more cellular networks via two or more radio access technologies. In some aspects, the radio signal transceivers 608 and/or the cellular network wireless modem chip(s) 616 may be configured to receive EM emissions from a plurality of electronic devices as described above, while in other aspects an optional EM emissions sensor 617 may be coupled to the processor 602 and the antennae 610.

The mobile communication device 600 may include a peripheral device connection interface 618 coupled to the processor 602. The peripheral device connection interface 618 may be singularly configured to accept one type of connection, or may be configured to accept various types of physical and communication connections, common or proprietary, such as USB, FireWire, Thunderbolt, or PCIe. The peripheral device connection interface 618 may also be coupled to a similarly configured peripheral device connection port (not shown). The mobile communication device 600 may also include speakers 614 for providing audio outputs. The mobile communication device 600 may also include a housing 620, constructed of a plastic, metal, or a combination of materials, for containing all or some of the components discussed herein. The mobile communication device 600 may include a power source 622 coupled to the processor 602, such as a disposable or rechargeable battery. The rechargeable battery may also be coupled to the peripheral device connection port to receive a charging current from a source external to the mobile communication device 600. The mobile communication device 600 may also include a physical button 624 for receiving user inputs. The mobile communication device 600 may also include a power button 626 for turning the mobile communication device 600 on and off.

The processor 602 may be any programmable microprocessor, microcomputer or multiple processor chip or chips that can be configured by software instructions (applications) to perform a variety of functions, including the functions of various aspects described below. In some mobile communication devices, multiple processors 602 may be provided, such as one processor dedicated to wireless communication functions and one processor dedicated to running other applications. Typically, software applications may be stored in the internal memory 604 before they are accessed and loaded into the processor 602. The processor 602 may include internal memory sufficient to store the application software instructions. In various aspects, the processor 612 may be a device processor, processing core, or an SOC (such as the example SOC 100 illustrated in FIG. 1). In an aspect, the mobile communication device 700 may include an SOC, and the processor 702 may be one of the processors included in the SOC (such as one of the processors 101, 104, 106, 108, and 110 illustrated in FIG. 1).

Computer code or program code for execution on a programmable processor for carrying out operations of the various aspects may be written in a high level programming language such as C, C++, C#, Smalltalk, Java, JavaScript, Visual Basic, a Structured Query Language (e.g., Transact-SQL), Perl, or in various other programming languages. Program code or programs stored on a computer readable storage medium as used in this application may refer to machine language code (such as object code) whose format is understandable by a processor.

Many mobile receiving devices operating system kernels are organized into a user space (where non-privileged code runs) and a kernel space (where privileged code runs). This separation is of particular importance in Android® and other general public license (GPL) environments where code that is part of the kernel space must be GPL licensed, while code running in the user-space may not be GPL licensed. It should be understood that the various software components/modules discussed herein may be implemented in either the kernel space or the user space, unless expressly stated otherwise.

The foregoing method descriptions and the process flow diagrams are provided merely as illustrative examples, and are not intended to require or imply that the operations of the various aspects must be performed in the order presented. As will be appreciated by one of skill in the art the order of operations in the foregoing aspects may be performed in any order. Words such as “thereafter,” “then,” “next,” etc. are not intended to limit the order of the operations; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the various aspects.

The hardware used to implement the various illustrative logics, logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a multiprocessor, but, in the alternative, the processor may be any conventional processor, controller, microcontroller, or state machine. A processor may also be implemented as a combination of receiving devices, e.g., a combination of a DSP and a multiprocessor, a plurality of multiprocessors, one or more multiprocessors in conjunction with a DSP core, or any other such configuration. Alternatively, some operations or methods may be performed by circuitry that is specific to a given function.

In one or more exemplary aspects, the functions described may be implemented in hardware, software, firmware, or any combination thereof. If implemented in software, the functions may be stored as one or more processor-executable instructions or code on a non-transitory computer-readable storage medium or non-transitory processor-readable storage medium. The operations of a method or algorithm disclosed herein may be embodied in a processor-executable software module, which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed aspects is provided to enable any person skilled in the art to make or use the various aspects. Various modifications to these aspects will be readily apparent to those skilled in the art, and the generic principles defined herein may be applied to other aspects without departing from the spirit or scope of the various aspects. Thus, the various aspects are not intended to be limited to the aspects shown herein but is to be accorded the widest scope consistent with the following claims and the principles and novel features disclosed herein.

What is claimed is:

1. A method of detecting anomalous electromagnetic (EM) emissions from among a plurality of electronic devices by a receiving device, comprising:
receiving EM emissions of a plurality of electronic devices, wherein the receiving device has no previous information about any of the plurality of electronic devices;
cross-correlating the EM emissions of the plurality of electronic devices over time;
identifying a difference of the cross-correlated EM emissions from earlier cross-correlated EM emissions; and
determining that the difference of the cross-correlated EM emissions from the earlier cross-correlated EM emissions indicates an anomaly in one or more of the plurality of electronic devices.

2. The method of claim 1, wherein cross-correlating the EM emissions of the plurality of electronic devices over time comprises calculating a trend of the cross-correlated EM emissions over time using a statistical analysis of the EM emissions.

3. The method of claim 2, wherein identifying a difference of the cross-correlated EM emissions from earlier cross-correlated EM emissions comprises identifying a difference of the cross-correlated EM emissions and the calculated trend.

4. The method of claim 3, wherein determining that the difference of the cross-correlated EM emissions from the earlier cross-correlated EM emissions indicates an anomaly in one or more of the plurality of electronic devices comprises determining that the difference of the cross-correlated EM emissions and the calculated trend indicates an anomaly in one or more of the plurality of electronic devices.

5. The method of claim 2, wherein calculating a trend of the cross-correlated EM emissions over time using a statistical analysis of the EM emissions comprises determining a trend characteristic of the calculated trend.

6. The method of claim 5, wherein the trend characteristic comprises one or more of a lock-step trend, a time-shifted trend, and a substantially uncorrelated trend.

7. The method of claim 5, wherein identifying a difference of the cross-correlated EM emissions from earlier cross-correlated EM emissions comprises identifying a difference of the cross-correlated EM emissions and the determine trend characteristic.

8. The method of claim 7, wherein determining that the difference of the cross-correlated EM emissions from the earlier cross-correlated EM emissions indicates an anomaly in one or more of the plurality of electronic devices comprises determining that the difference of the cross-correlated EM emissions and the determine trend characteristic indicates an anomaly in one or more of the plurality of electronic devices.

9. The method of claim 1, wherein identifying a difference of the cross-correlated EM emissions from earlier cross-correlated EM emissions comprises:
determining at least one anomaly threshold based on the cross-correlated EM emissions of the plurality of electronic devices over time;
comparing the cross-correlated EM emissions of the plurality of electronic devices to the at least one anomaly threshold; and
calculating a difference from the cross-correlated EM emissions relative to the determined at least one anomaly threshold.

10. The method of claim 9, wherein determining that the difference of the cross-correlated EM emissions from the earlier cross-correlated EM emissions indicates an anomaly in one or more of the plurality of electronic devices comprises determining that the calculated difference from the cross-correlated EM emissions meets the at least one anomaly threshold.

11. A computing device, comprising:
an electromagnetic (EM) emissions sensor configured to receive EM emissions from a plurality of electronic devices; and
a processor configured with processor-executable instructions to perform operations comprising:
receiving EM emissions of a plurality of electronic devices, wherein the processor has no previous information about any of the plurality of electronic devices;
cross-correlating the EM emissions of the plurality of electronic devices over time;
identifying a difference of the cross-correlated EM emissions from earlier cross-correlated EM emissions; and
determining that the difference of the cross-correlated EM emissions from the earlier cross-correlated EM emissions indicates an anomaly in one or more of the plurality of electronic devices.

12. The computing device of claim 11, wherein the processor is configured with processor-executable instructions to perform operations such that cross-correlating the EM emissions of the plurality of electronic devices over time comprises calculating a trend of the cross-correlated EM emissions over time using a statistical analysis of the EM emissions.

13. The computing device of claim 12, wherein the processor is configured with processor-executable instructions to perform operations such that identifying a difference of the cross-correlated EM emissions from earlier cross-correlated EM emissions comprises identifying a difference of the cross-correlated EM emissions and the calculated trend.

14. The computing device of claim 13, wherein the processor is configured with processor-executable instructions to perform operations such that determining that the difference of the cross-correlated EM emissions from the earlier cross-correlated EM emissions indicates an anomaly in one or more of the plurality of electronic devices comprises determining that the difference of the cross-correlated EM emissions and the calculated trend indicates an anomaly in one or more of the plurality of electronic devices.

15. The computing device of claim 12, wherein the processor is configured with processor-executable instructions to perform operations such that calculating a trend of the cross-correlated EM emissions over time using a statistical analysis of the EM emissions comprises determining a trend characteristic of the calculated trend.

16. The computing device of claim 15, wherein the processor is configured with processor-executable instructions to perform operations such that the trend characteristic comprises one or more of a lock-step trend, a time-shifted trend, and a substantially uncorrelated trend.

17. The computing device of claim 15, wherein the processor is configured with processor-executable instructions to perform operations such that identifying a difference of the cross-correlated EM emissions from earlier cross-correlated EM emissions comprises identifying a difference of the cross-correlated EM emissions and the determine trend characteristic.

18. The computing device of claim 17, wherein the processor is configured with processor-executable instructions to perform operations such that determining that the difference of the cross-correlated EM emissions from the earlier cross-correlated EM emissions indicates an anomaly in one or more of the plurality of electronic devices comprises determining that the difference of the cross-correlated EM emissions and the determine trend characteristic indicates an anomaly in one or more of the plurality of electronic devices.

19. The computing device of claim 11, wherein the processor is configured with processor-executable instructions to perform operations such that identifying a difference of the cross-correlated EM emissions from earlier cross-correlated EM emissions comprises:
determining at least one anomaly threshold based on the cross-correlated EM emissions of the plurality of electronic devices over time;
comparing the cross-correlated EM emissions of the plurality of electronic devices to the at least one anomaly threshold; and
calculating a difference from the cross-correlated EM emissions relative to the determined at least one anomaly threshold.

20. The computing device of claim 19, wherein the processor is configured with processor-executable instructions to perform operations such that determining that the difference of the cross-correlated EM emissions from the earlier cross-correlated EM emissions indicates an anomaly in one or more of the plurality of electronic devices comprises determining that the calculated difference from the cross-correlated EM emissions meets the at least one anomaly threshold.

21. A non-transitory processor-readable storage medium having stored thereon processor-executable software instructions configured to cause a processor of a receiving device to perform operations for detecting anomalous electromagnetic (EM) emissions from among a plurality of electronic devices, comprising:
receiving EM emissions of a plurality of electronic devices, wherein the processor of a receiving device has no previous information about any of the plurality of electronic devices;
cross-correlating the EM emissions of the plurality of electronic devices over time;
identifying a difference of the cross-correlated EM emissions from earlier cross-correlated EM emissions; and
determining that the difference of the cross-correlated EM emissions from the earlier cross-correlated EM emissions indicates an anomaly in one or more of the plurality of electronic devices.

22. The non-transitory processor-readable storage medium of claim 21, wherein the stored processor-executable software instructions are configured to cause a processor of a receiving device to perform operations such that cross-correlating the EM emissions of the plurality of electronic devices over time comprises calculating a trend of the cross-correlated EM emissions over time using a statistical analysis of the EM emissions.

23. The non-transitory processor-readable storage medium of claim 22, wherein the stored processor-executable software instructions are configured to cause a processor of a receiving device to perform operations such that identifying a difference of the cross-correlated EM emissions from earlier cross-correlated EM emissions comprises identifying a difference of the cross-correlated EM emissions and the calculated trend.

24. The non-transitory processor-readable storage medium of claim 23, wherein the stored processor-executable software instructions are configured to cause a processor of a receiving device to perform operations such that determining that the difference of the cross-correlated EM emissions from the earlier cross-correlated EM emissions indicates an anomaly in one or more of the plurality of electronic devices comprises determining that the difference of the cross-correlated EM emissions and the calculated trend indicates an anomaly in one or more of the plurality of electronic devices.

25. The non-transitory processor-readable storage medium of claim 22, wherein the stored processor-executable software instructions are configured to cause a processor of a receiving device to perform operations such that calculating a trend of the cross-correlated EM emissions over time using a statistical analysis of the EM emissions comprises determining a trend characteristic of the calculated trend.

26. The non-transitory processor-readable storage medium of claim 25, wherein the stored processor-executable software instructions are configured to cause a processor of a receiving device to perform operations such that the trend characteristic comprises one or more of a lock-step trend, a time-shifted trend, and a substantially uncorrelated trend.

27. The non-transitory processor-readable storage medium of claim 25, wherein the stored processor-executable software instructions are configured to cause a processor of a receiving device to perform operations such that identifying a difference of the cross-correlated EM emissions from earlier cross-correlated EM emissions comprises identifying a difference of the cross-correlated EM emissions and the determine trend characteristic.

28. The non-transitory processor-readable storage medium of claim 27, wherein the stored processor-executable software instructions are configured to cause a processor of a receiving device to perform operations such that determining that the difference of the cross-correlated EM emissions from the earlier cross-correlated EM emissions indicates an anomaly in one or more of the plurality of electronic devices comprises determining that the difference of the cross-correlated EM emissions and the determine trend characteristic indicates an anomaly in one or more of the plurality of electronic devices.

29. The non-transitory processor-readable storage medium of claim 21, wherein the stored processor-executable software instructions are configured to cause a processor of a receiving device to perform operations such that identifying a difference of the cross-correlated EM emissions from earlier cross-correlated EM emissions comprises:
determining at least one anomaly threshold based on the cross-correlated EM emissions of the plurality of electronic devices over time;
comparing the cross-correlated EM emissions of the plurality of electronic devices to the at least one anomaly threshold; and
calculating the difference from the cross-correlated EM emissions relative to the determined at least one anomaly threshold.

30. A computing device, comprising:
means for receiving EM emissions of a plurality of electronic devices, wherein the computing device has no previous information about any of the plurality of electronic devices;
means for cross-correlating the EM emissions of the plurality of electronic devices over time;
means for identifying a difference of the cross-correlated EM emissions from earlier cross-correlated EM emissions; and
means for determining that the difference of the cross-correlated EM emissions from the earlier cross-correlated EM emissions indicates an anomaly in one or more of the plurality of electronic devices.
